(19) United States
(12) Patent Application Publication
(10) Pub. No.: US 2026/0249425 A1
(43) Pub. Date: Aug. 27, 2026

(54) DRESSER, METHOD OF MANUFACTURING DRESSER, AND METHOD OF MANUFACTURING SEMICONDUCTOR DEVICE

(71) Applicant: Kioxia Corporation, Tokyo (JP)

(72) Inventor: Takeshi ARAKAWA, Yokkaichi (JP)

(73) Assignee: Kioxia Corporation, Tokyo (JP)

(21) Appl. No.: 19/314,736

(22) Filed: Aug. 29, 2025

(30) Foreign Application Priority Data
Feb. 26, 2025 (JP) 2025-029108

(51) Int. Cl. B24B 53/017; B24B 53/12; H01L 21/306

(52) U.S. Cl. CPC B24B 53/017; B24B 53/12; H10P 52/402

(57) ABSTRACT

According to one embodiment, a dresser includes a first layer including a portion and a protrusion provided on the portion. The dresser includes a second layer including a first region provided on the protrusion and having a first thickness and a second region provided on the protrusion, positioned on a side of an upper end of the protrusion relative to the first region, and having a second thickness thicker than the first thickness. In a cross-section including the upper end of the protrusion, the protrusion includes a first surface positioned on one side of the upper end of the protrusion and a second surface positioned on another side of the upper end of the protrusion. The second region is provided on the upper end, the first surface, and the second surface of the protrusion.

### CROSS-REFERENCE TO RELATED APPLICATION

This application is based upon and claims the benefit of priority from Japanese Patent Application No. 2025-029108, filed Feb. 26, 2025, the entire contents of which are incorporated herein by reference.

### FIELD

Embodiments described herein relate generally to a dresser, a method of manufacturing a dresser, and a method of manufacturing a semiconductor device.

### BACKGROUND

In a polishing device such as a chemical mechanical polishing (CMP) device, a surface of a polishing pad may be dressed using a dresser including a protrusion covered by a film. Here, when the dresser is continuously used, there is a problem in that the film of the protrusion is thinned and polishing performance of the dresser deteriorates.

### DESCRIPTION OF THE DRAWINGS

FIG. 1 is a perspective view illustrating a configuration of a polishing device according to a first embodiment;

FIGS. 2A and 2B are perspective views illustrating two examples of a structure of a dresser according to the first embodiment;

FIG. 3 is a cross-sectional view illustrating a structure of a dressing member according to the first embodiment;

FIGS. 4A to 4C are plan views illustrating three examples of the structure of the dressing member according to the first embodiment;

FIGS. 5A and 5B are cross-sectional views illustrating a problem of a dressing member according to a comparative example of the first embodiment;

FIG. 6 is a graph for comparison between the dressing member according to the first embodiment and the dressing member according to the comparative example;

FIGS. 7A to 7C are cross-sectional views illustrating a first example of a method of manufacturing the dressing member according to the first embodiment;

FIGS. 8A to 8C are cross-sectional views illustrating a second example of the method of manufacturing the dressing member according to the first embodiment;

FIGS. 9A to 9C are cross-sectional views (1/2) illustrating the method of manufacturing the dressing member according to the first embodiment;

FIGS. 10A to 10C are cross-sectional views (2/2) illustrating the method of manufacturing the dressing member according to the first embodiment;

FIG. 11 is a cross-sectional view illustrating a structure of a dressing member according to a second embodiment;

FIGS. 12A and 12B are cross-sectional views illustrating a method of manufacturing the dressing member according to the second embodiment;

FIG. 13 is a cross-sectional view illustrating a structure of a dressing member according to a third embodiment;

FIGS. 14A and 14B are cross-sectional views (1/4) illustrating a method of manufacturing the dressing member according to the third embodiment;

FIGS. 15A and 15B are cross-sectional views (2/4) illustrating the method of manufacturing the dressing member according to the third embodiment;

FIGS. 16A and 16B are cross-sectional views (3/4) illustrating the method of manufacturing the dressing member according to the third embodiment;

FIGS. 17A and 17B are cross-sectional views (4/4) illustrating the method of manufacturing the dressing member according to the third embodiment;

FIGS. 18A and 18B are cross-sectional views (1/2) illustrating a method of manufacturing a dressing member according to a fourth embodiment;

FIGS. 19A and 19B are cross-sectional views (2/2) illustrating the method of manufacturing the dressing member according to the fourth embodiment; and

FIGS. 20A and 20B are cross-sectional views illustrating a method of manufacturing a dressing member according to a modification example of the fourth embodiment.

### DETAILED DESCRIPTION

Embodiments provide a dresser, a method of manufacturing a dresser, and a method of manufacturing a semiconductor device in which a suitable film can be provided on a surface of a protrusion for dressing.

In general, according to one embodiment, a dresser includes a first layer including a plate-shaped portion and a protrusion provided on the plate-shaped portion. The dresser further includes a second layer including a first region provided on the protrusion and having a first film thickness and a second region provided on the protrusion, positioned on a side of an upper end of the protrusion relative to the first region, and having a second film thickness thicker than the first film thickness. In a cross-section including the upper end of the protrusion, the protrusion includes a first surface positioned on one side of the upper end of the protrusion and a second surface positioned on another side of the upper end of the protrusion. The second region is provided on the upper end, the first surface, and the second surface of the protrusion.

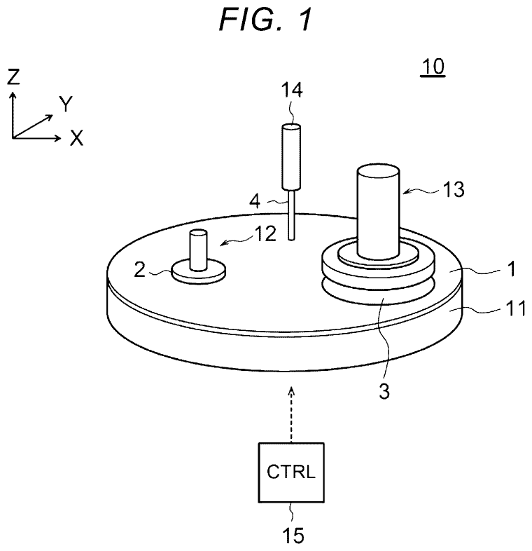

Hereinafter, embodiments of the present disclosure will be described with respect to the drawings. In FIGS. 1 to 20B, the same components are represented by the same reference numerals, and the detailed description thereof will not be repeated.

### First Embodiment

FIG. 1 is a perspective view illustrating a configuration of a polishing apparatus 10 according to a first embodiment. The polishing apparatus 10 is, for example, a CMP apparatus.

The polishing apparatus 10 includes a polishing table 11, a dressing mechanism 12, a polishing head 13, a slurry supply unit 14, and a control unit 15.

FIG. 1 illustrates an X direction, a Y direction, and a Z direction perpendicular to each other. In the specification, a +Z direction is regarded as an upward direction, a −Z direction is regarded as a downward direction, and the −Z direction may match with a gravity direction or may not match with a gravity direction.

The polishing table 11 holds and rotates a polishing pad 1. In FIG. 1, the polishing table 11 holds the polishing pad 1 such that a surface of the polishing pad 1 faces the +Z direction, and rotates the polishing pad 1 on an XY plane.

The dressing mechanism 12 dresses (conditioning) the polishing pad 1 using a dresser 2. In FIG. 1, the dressing mechanism 12 holds the dresser 2 such that a surface of the dresser 2 faces the −Z direction, and brings the surface of the dresser 2 into contact with the surface of the polishing pad 1. Accordingly, the surface of the polishing pad 1 is dressed by the dresser 2. The dresser 2 is also called a conditioner.

The polishing head 13 holds a wafer 3 to be polished using the polishing pad 1. In FIG. 1, the polishing head 13 holds the wafer 3 such that a surface of the wafer 3 faces the −Z direction, and brings the surface of the wafer 3 into contact with the surface of the polishing pad 1. Accordingly, the surface of the wafer 3 is polished using the polishing pad 1. The wafer 3 is used for manufacturing a plurality of semiconductor devices (semiconductor chips), for example.

The slurry supply unit 14 supplies slurry 4 to the polishing pad 1. In the polishing apparatus 10, the slurry supply unit 14 supplies the slurry 4 onto the surface of the polishing pad 1, the polishing table 11 rotates the polishing pad 1, and the polishing head 13 brings the surface of the wafer 3 into contact with the surface of the polishing pad 1. Accordingly, the surface of the wafer 3 is polished using the polishing pad 1 onto which the slurry 4 is supplied.

The control unit 15 controls operations of the polishing apparatus 10. For example, the control unit 15 controls rotation of the polishing pad 1 by the polishing table 11, movement of the dresser 2 by the dressing mechanism 12, movement of the wafer 3 by the polishing head 13, supply of the slurry 4 from the slurry supply unit 14, and the like.

In the present embodiment, the polishing pad 1 is dressed using the dresser 2, the wafer 3 is polished using the dressed polishing pad 1, and a plurality of semiconductor devices are manufactured using the polished wafer 3. Dressing of the polishing pad 1 or polishing of the wafer 3 is performed using the polishing apparatus 10 as described above. By dicing the wafer 3 into a plurality of semiconductor chips, a plurality of semiconductor devices are manufactured from the wafer 3.

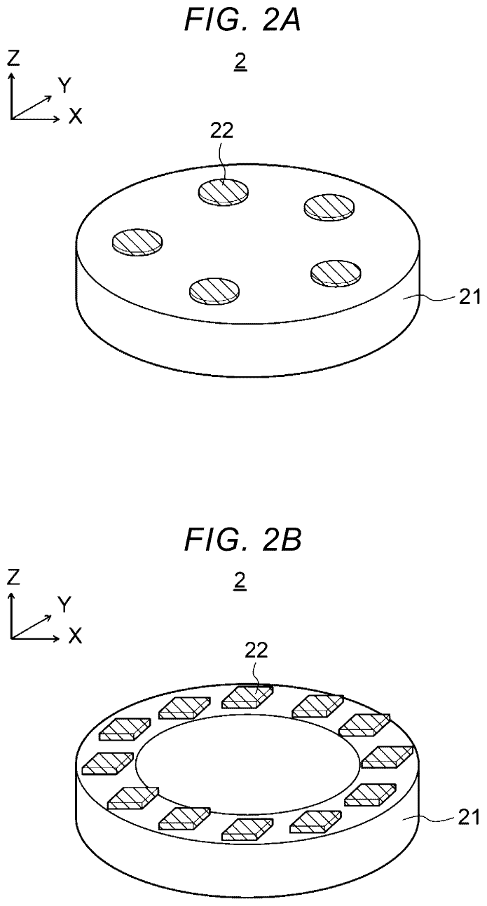

FIGS. 2A and 2B are perspective views illustrating two examples of a structure of the dresser 2 according to the first embodiment.

FIG. 2A illustrates a first example of the structure of the dresser 2. The dresser 2 illustrated in FIG. 2A includes a support member (support plate) 21 and one or a plurality of dressing members (dressing chip) 22.

In FIG. 2A, the support member 21 has a disk shape, and one or a plurality dressing members 22 are arranged in an annular shape on a working surface of the support member 21. The working surface of the support member 21 is a surface that faces the polishing pad 1 in FIG. 1. In FIG. 2A, the dresser 2 is disposed such that the working surface of the support member 21 is an upper surface of the support member 21. However, in FIG. 1, the dresser 2 is held such that the working surface of the support member 21 is a lower surface of the support member 21. In the present embodiment, the surface of the polishing pad 1 is dressed by each of the dressing members 22.

The number of the dressing members 22 on the support member 21 is five in FIG. 2A, but is not limited thereto. To dress the polishing pad 1 uniformly, the number of the dressing members 22 on the support member 21 is desirably two or more, and arrangement of the dressing members 22 on the support member 21 is desirably symmetrical.

FIG. 2B illustrates a second example of the structure of the dresser 2. The dresser 2 illustrated in FIG. 2B also includes the support member 21 and one or a plurality of dressing members 22.

The dresser 2 illustrated in FIG. 2B has the same structure as the dresser 2 illustrated in FIG. 2A. The support member 21 of FIG. 2A has a solid disk shape, that is, a circular shape, whereas the support member 21 of FIG. 2B has a hollow disk shape, that is, an annular shape. For example, the support member 21 of FIG. 2B is a base formed of metal, and each of the dressing members 22 of FIG. 2B is a chip manufactured from the wafer. The number of the dressing members 22 on the support member 21 is 12 in FIG. 2B, but is not limited thereto.

Hereinafter, the dressing member 22 will be described more specifically. In the following description, the dressing member 22 is assumed to be the dressing member 22 illustrated in FIG. 2A. However, the following description is also applicable to the dressing member 22 illustrated in FIG. 2B.

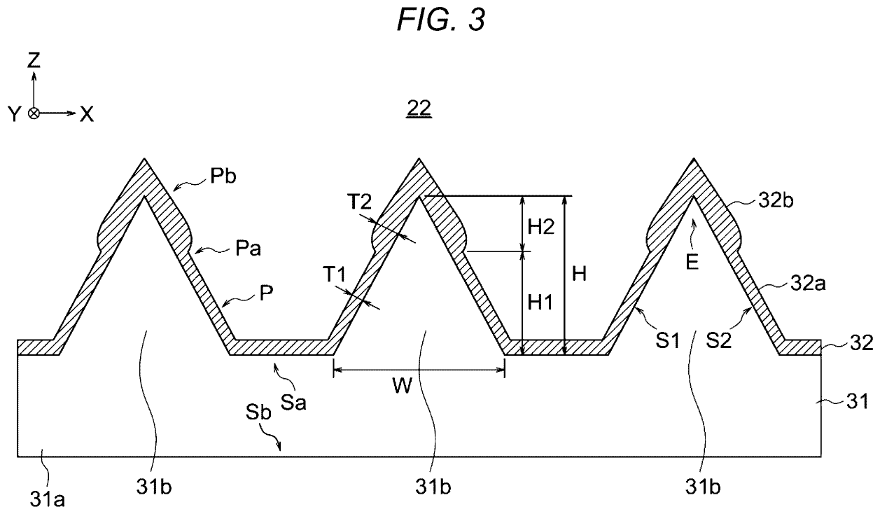

FIG. 3 is a cross-sectional view illustrating a structure of the dressing member 22 according to the first embodiment.

The dressing member 22 includes an underlying member 31 as an example of the first layer and a film 32 as an example of the second layer. The underlying member 31 includes a plate-shaped portion 31a and a plurality of protrusions 31b. The film 32 includes a lower region 32a and a plurality of upper regions 32b. The lower region 32a is an example of a first region, and each of the upper regions 32b is an example of a second region.

### Underlying Member 31

The underlying member 31 is an underlayer of the film 32 in the dressing member 22. The underlying member 31 is, for example, silicon (Si) layer or a silicon carbide (SiC) layer. A first example of the underlying member 31 is a semiconductor substrate such as a Si substrate or a SiC substrate. A second example of the underlying member 31 is a SiC member formed of a SiC sintering material. The examples will be described below in more detail.

The plate-shaped portion 31a has a plate-shaped shape extending in the X direction and the Y direction. In FIG. 3, an upper surface Sa and a lower surface Sb of the plate-shaped portion 31a are parallel to the X direction and the Y direction, and are perpendicular to the Z direction. In FIG. 2A, the dressing member 22 is disposed on the support member 21 such that the lower surface Sb of the plate-shaped portion 31a faces the working surface of the support member 21.

Each of the protrusions 31b is provided on the plate-shaped portion 31a, and protrudes in the +Z direction from the upper surface Sa of the plate-shaped portion 31a. A shape of each of the protrusions 31b in a plan view is, for example, a conical or pyramid shape having a central axis parallel to the Z direction. FIG. 3 illustrates a width W of each of the protrusions 31b in the X direction and an upper end (tip) E of each of the protrusions 31b. When each of the protrusions 31b has a conical shape, the width W is the diameter of a bottom surface of the conical shape, and the upper end E is an apex of the conical shape. The width W is, for example, 100 to 500 μm. The dressing member 22 according to the present embodiment includes a plurality of protrusions 31b formed on the plate-shaped portion 31a in a two-dimensional array.

When each of the protrusions 31b has a conical or pyramid shape, a shape of an XZ cross-section including the upper end E of each of the protrusions 31b is a triangular shape as illustrated in FIG. 3. The same applies to vertical cross-sections other than the XZ cross-section. In the XZ cross-section illustrated in FIG. 3, each of the protrusions 31b includes a surface S1 positioned on one side (−X direction) of the upper end E and a surface S2 positioned on another side (+X direction) of the upper end E, and the upper end E is provided between the surface S1 and the surface S2. When each of the protrusions 31b has a conical shape, the surfaces S1 and S2 correspond to two portions of one side surface of the conical shape. When each of the protrusions 31b has a pyramid shape, the surfaces S1 and S2 correspond to two side surfaces among a plurality of side surfaces of the pyramid shape. The surfaces S1 and S2 are examples of first and second surfaces. Regarding each of the protrusions 31b illustrated in FIG. 3, FIG. 3 illustrates a cross-section including the upper end E of each of the protrusions 31b.

### Film 32

The film 32 is formed to cover the underlying member 31 of the dressing member 22. The film 32 is, for example, a diamond layer. In FIG. 3, the film 32 is formed on an entire upper surface of the underlying member 31. Accordingly, the upper surface Sa of the plate-shaped portion 31a and the surface of each of the protrusions 31b are covered by the film 32. In the present embodiment, the film 32 is a diamond thin film formed thinly on the surface of each of the protrusions 31b. As a result, each of the protrusions 31b and the film 32 on the surface of each of the protrusions 31b form one protrusion slightly larger than each of the protrusions 31b. The film 32 may be a layer other than a diamond layer, and for example, may be a carbon (C) layer that is not a diamond layer. Examples of the C layer include a diamond-like carbon (DLC) layer and a hard C layer other than the DLC layer. The hard C layer has a Vickers hardness (HV) of, for example, 5000 or more. The film 32 may be a hard layer that does not include carbon, and such a hard layer may have a Vickers hardness of, for example, 5000 or more.

The film 32 includes the lower region 32a having a film thickness T1 and a plurality of upper regions 32b having a film thickness T2 thicker than the film thickness T1. The lower region 32a is formed on the upper surface Sa of the plate-shaped portion 31a or a part of the surface of each of the protrusions 31b. Each of the upper regions 32b is formed on a part of the surface of one protrusion 31b, and is positioned on a side of the upper end E of the protrusion 31b relative to the lower region 32a. Accordingly, in each of the protrusions 31b, a lower portion of the protrusion 31b is covered by the lower region 32a, and an upper portion of the protrusion 31b is covered by one upper region 32b. As illustrated in FIG. 3, the upper region 32b is formed on the upper end E, the surface S1, and the surface S2 of the protrusion 31b, and is formed such that the upper end E is interposed between the surface S1 and the surface S2 in the XZ cross-section of the protrusion 31b. The film thickness T1 is an example of a first film thickness, and the film thickness T2 is an example of a second film thickness.

The film thickness T1 of the lower region 32a according to the present embodiment is substantially fixed. The film thickness T1 is, for example, 1 μm or more (T1≥1 μm), and may be 5 μm or more (T1≥5 μm). Meanwhile, the film thickness T2 of each of the upper regions 32b according to the present embodiment changes near a boundary between the lower region 32a and the upper region 32b, and is substantially fixed at positions away from the boundary. In the present embodiment, a difference obtained by subtracting the film thickness T1 from the film thickness T2 at the positions away from the boundary is, for example, 1 μm or more and 5 μm or less (1 μm≤T2−T1≤5 μm). In the present embodiment, the lower region 32a is formed using a diamond layer having a film thickness of 1 μm or more, and each of the upper regions 32b is formed using the same diamond layer and another diamond layer having a film thickness of 1 μm or more and 5 μm or less. Accordingly, “T1” described above is 1 μm or more due to the former diamond layer, and “T2−T1” described above is 1 μm or more and 5 μm or less due to the latter diamond layer.

FIG. 3 also illustrates a height H from the upper surface Sa of the plate-shaped portion 31a to the upper end E of each of the protrusions 31b. The height H corresponds to a height of each of the protrusions 31b. FIG. 3 also illustrates a height H1 from the upper surface Sa of the plate-shaped portion 31a to the boundary between the lower region 32a and the upper region 32b and a height H2 from the same boundary to the upper end E of each of the protrusions 31b. The heights H, H1, and H2 satisfy a relationship of H=H1+H2. For example, the height H is 100 to 500 μm, and the height H2 is 10 to 50 μm.

FIG. 3 also illustrates portions P, Pa, and Pb of the surface of the film 32 on each of the protrusions 31b. The portion P is a surface of the lower region 32a, and the portion Pb is a surface of the upper region 32b. Since the film thickness T2 is thicker than the film thickness T1, the portion Pb protrudes from the portion P in a direction away from the surface of the protrusion 31b. Meanwhile, the portion Pa is a surface between the portion P and the portion Pb. In the present embodiment, the film thickness T2 changes near a boundary between the lower region 32a and the upper region 32b. Specifically, the film thickness T2 increases toward the upper end E. Therefore, the portion Pa (e.g., recessed portion Pa) is recessed between the portion P and the portion Pb. That is, the surface of the film 32 is recessed near the boundary between the lower region 32a and the upper region 32b. For example, the recessed portion Pa may include the boundary between the lower region 32a and the upper region 32b. In the present embodiment, a shape of the portion Pa in a plan view is annular. The surface of the film 32 according to the present embodiment is recessed in the portion Pa, and protrudes in the portion Pb.

As described above, the dressing member 22 according to the present embodiment includes a plurality of protrusions 31b provided on the plate-shaped portion 31a, and the protrusions 31b are covered by the film 32. The dresser 2 according to the present embodiment dresses the polishing pad 1 using the protrusions 31b and the film 32.

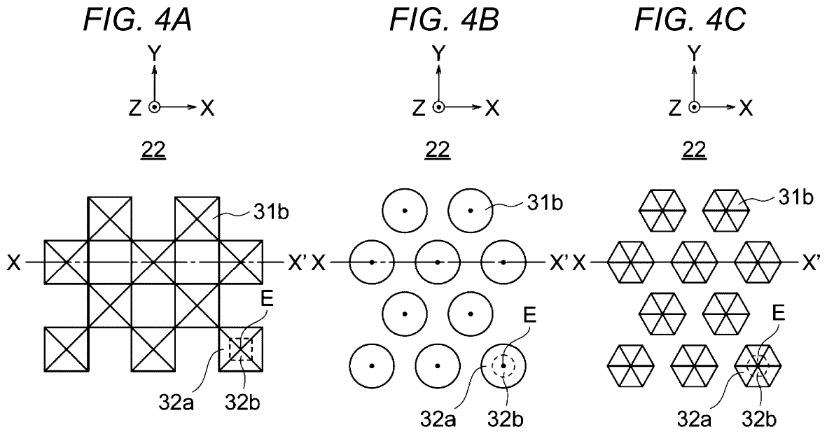

FIGS. 4A to 4C are plan views illustrating three examples of the structure of the dressing member 22 according to the first embodiment.

FIG. 4A illustrates a first example of a layout of the plurality of protrusions 31b in the dressing member 22. In FIG. 4A, the protrusions 31b are arranged in a two-dimensional array, and a shape of each of the protrusions 31b is a quadrangular pyramid. FIG. 3 illustrates an XZ cross-section taken along a line X-X′ illustrated in FIG. 4A.

FIG. 4A also illustrates shapes of the lower region 32a and the upper region 32b on one protrusion 31b. In FIG. 4A, the lower region 32a surrounds the upper region 32b in a plan view, and the upper region 32b overlaps the upper end E of the protrusion 31b in a plan view.

The same applies to FIGS. 4B and 4C. FIG. 4B illustrates a second example of the layout of the plurality of protrusions 31b in the dressing member 22. FIG. 4C illustrates a third example of the layout of the plurality of protrusions 31b in the dressing member 22. A shape of each of the protrusions 31b illustrated in FIG. 4B is a conical shape. A shape of each of the protrusions 31b illustrated in FIG. 4C is a hexagonal pyramid shape.

A shape of each of the protrusions 31b according to the present embodiment may be a pyramid shape other than the quadrangular pyramid shape or the hexagonal pyramid shape, or may be a three-dimensional shape other than the conical shape or the pyramid shape.

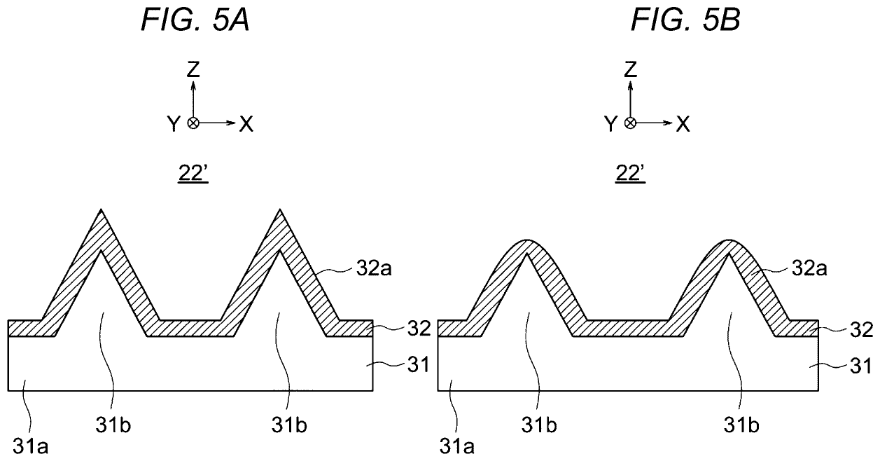

FIGS. 5A and 5B are cross-sectional views illustrating problems of a dressing member 22′ according to a comparative example of the first embodiment.

FIG. 5A illustrates the dressing member 22′ according to the comparative example. The dressing member 22′ according to the comparative example includes the underlying member 31 and the film 32 as in the dressing member 22 according to the first embodiment. The film 32 according to the comparative example has the same film thickness in all portions of the film 32 as illustrated in FIG. 5A.

Here, when the dresser 2 is continuously used, there is a problem in that the film 32 of each of the protrusions 31b is thinned and polishing performance of the dresser 2 deteriorates. As illustrated in FIG. 5B, the film 32 of each of the protrusions 31b is more easily thinned near the upper end E of each of the protrusions 31b due to wearing. When the film 32 is thinned near the upper end E, the polishing performance of the dresser 2 largely deteriorates. In FIG. 5B, the film 32 is thinned near the upper end E, causing the shape of the film 32 near the upper end E to change from a pointed shape to a rounded shape.

Meanwhile, the film 32 according to the present embodiment is formed such that the film thickness T2 of the upper region 32b is thicker than the film thickness T1 of the lower region 32a. That is, the film 32 is formed to be thick near the upper end E. Accordingly, even when the film 32 is thinned near the upper end E by using the dresser 2, the film thickness of the film 32 near the upper end E can be maintained to be thicker than the film thickness of the film 32 at other positions. As compared to when the film 32 is formed in a uniform film thickness, the portion Pa is recessed and the portion Pb protrudes. Accordingly, the entire upper region 32b has the same wearing rate. Therefore, even when wearing of the film 32 progresses, an angle of the film 32 near the upper end E can be maintained. Thus, deterioration of the polishing performance of the dresser 2 can be reduced. As such, in the present embodiment, by forming the film 32 including the lower region 32a and the upper region 32b, a suitable film 32 can be formed on the surface of the protrusion 31b for dressing.

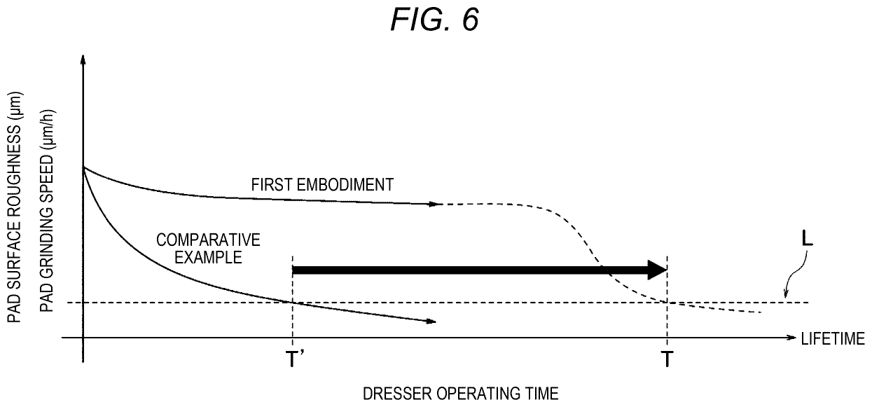

FIG. 6 is a graph for comparison between the dressing member 22 (dresser 2) according to the first embodiment and the dressing member 22′ (dresser 2) according to the comparative example.

A horizontal axis in FIG. 6 represents a total operating time of the dresser 2. A vertical axis in FIG. 6 represents a surface roughness (μm) and a grinding speed (μm/h) of the polishing pad 1 dressed by the dresser 2. When the dressers 2 according to the first embodiment and the comparative example are continuously used, the surface roughness or the grinding speed of the polishing pads 1 dressed by the dressers 2 change generally in a curve as illustrated in FIG. 6. A straight line L illustrated in FIG. 6 represents values of the surface roughness and the grinding speed when the dresser 2 reaches the end of the lifetime.

FIG. 6 also illustrates a timing T when the dresser 2 according to the first embodiment reaches end of lifetime and a timing T′ when the dresser 2 according to the comparative example reaches end of lifetime. When the dresser 2 according to the comparative example is continuously used, the dresser 2 reaches end of lifetime at the timing T′. Meanwhile, in the present embodiment, the dresser 2 can be continuously used until the timing T. In the present embodiment, by forming the film 32 including the lower region 32a and the upper region 32b, the lifetime of the dresser 2 can be increased.

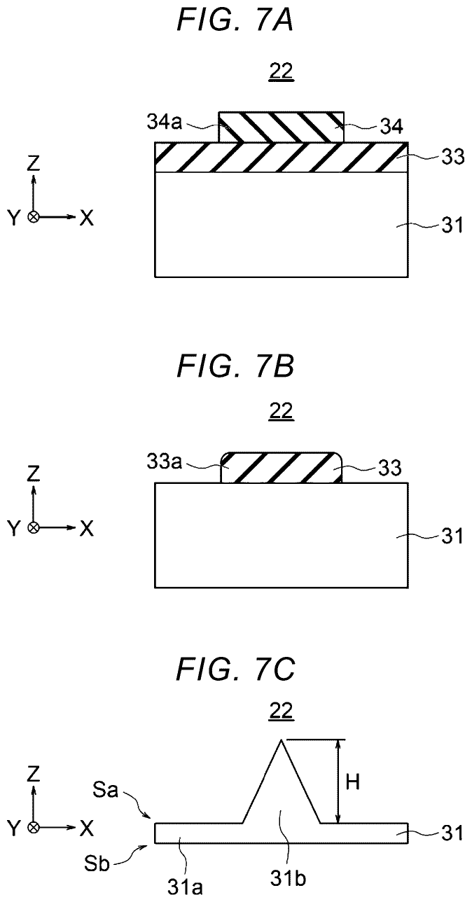

FIGS. 7A to 7C are cross-sectional views illustrating a first example of a method of manufacturing the dressing member 22 according to the first embodiment. FIGS. 7A to 7C illustrate an example of a method of forming each of the protrusions 31b of the underlying member 31 illustrated in FIG. 3.

First, a substrate is prepared as the underlying member 31 (FIG. 7A). The substrate is, for example, a semiconductor substrate such as a Si substrate or a SiC substrate. Next, a hard mask layer 33 is formed on the underlying member 31, and a resist layer 34 is formed on the hard mask layer 33 (FIG. 7A). The hard mask layer 33 is, for example, a tetraethyl orthosilicate (TEOS) film, a silicon oxide film (SiO₂ film), or a carbon film.

Next, the resist layer 34 is patterned by lithography and reactive ion etching (RIE) (FIG. 7A). As a result, a plurality of resist patterns 34a are formed from the resist layer 34. FIG. 7A illustrates one of the resist patterns 34a. For example, when the shape of each of the protrusions 31b is a conical shape, a planar shape of each of the resist patterns 34a is set to a circular shape. When the shape of each of the protrusions 31b is a pyramid shape, a planar shape of each of the resist patterns 34a is set to a polygonal shape. The planar shape of each of the resist patterns 34a may be set considering errors of lithography and RIE.

Next, the hard mask layer 33 is processed by RIE using the resist layer 34 as a mask (FIG. 7B). As a result, each of the resist patterns 34a is transferred onto the hard mask layer 33, and a plurality of mask patterns 33a are formed from the hard mask layer 33. FIG. 7B illustrates one of the mask patterns 33a.

Next, the underlying member 31 is processed by dry etching using the hard mask layer 33 as a mask (FIG. 7C). As a result, each of the mask patterns 33a is transferred onto a surface portion of the underlying member 31, and the plurality of protrusions 31b are formed in the underlying member 31. FIG. 7C illustrates one of the protrusions 31b. As illustrated in FIG. 7C, the surface portion of the underlying member 31 becomes the plurality of protrusions 31b, and the remaining portion of the underlying member 31 becomes the plate-shaped portion 31a. The shape of each of the protrusions 31b is, for example, a conical or pyramid shape depending on the planar shape of the resist patterns 34a. In the step of FIG. 7C, the underlying member 31 may be processed by wet etching instead of dry etching.

The dry etching of FIG. 7C is performed using, for example, mixed gas including SF₆ gas, C₄F₈ gas, and O₂ gas (S represents sulfur, F represents fluorine, C represents carbon, and O represents oxygen). When the hard mask layer 33 is a carbon film, dry etching may be performed using, for example, mixed gas including any one of HBr gas, Cl₂ gas, and NF₃ gas and O₂ gas (H represents hydrogen, Br represents bromine, Cl represents chlorine, and N represents nitrogen). In the present embodiment, each of the protrusions 31b can be processed into a conical or pyramid shape by dry etching.

The hard mask layer 33 is removed after performing dry etching. Each of the mask patterns 33a may be dropped between the protrusions 31b during or after dry etching. Here, the hard mask layer 33 including the dropped mask patterns 33a is removed. The hard mask layer 33 is removed, for example, by chemical treatment. Chemical treatment may be performed, for example, using a hydrofluoric acid aqueous solution or a mixed solution of sulfuric acid and a hydrogen peroxide solution.

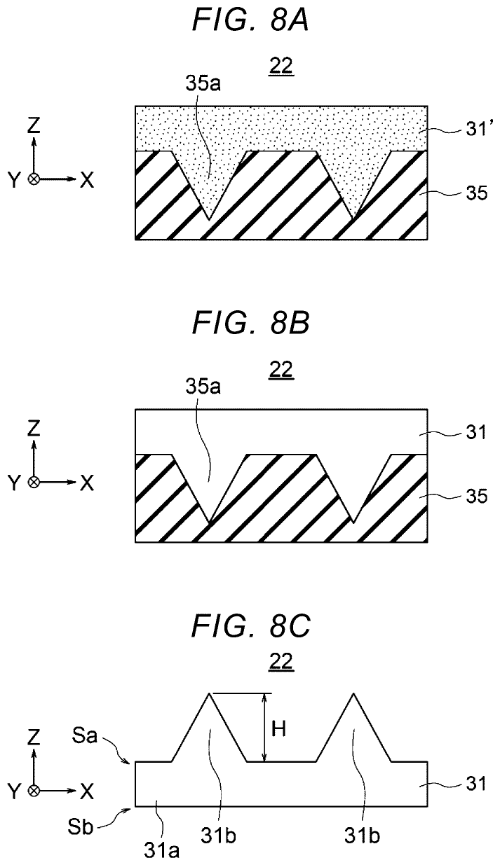

FIGS. 8A to 8C are cross-sectional views illustrating a second example of the method of manufacturing the dressing member 22 according to the first embodiment. FIGS. 8A to 8C illustrate an example of a method of forming each of the protrusions 31b of the underlying member 31 illustrated in FIG. 3.

First, a sintering mold 35 that is a mold for sintering is prepared (FIG. 8A). The sintering mold 35 includes a plurality of recess portions 35 for forming the plurality of protrusions 31b. A shape of each of the recess portions 35 is, for example, a conical or pyramid shape. Next, a sintering material 31′ is supplied onto an upper surface of the sintering mold 35 and into each of the recess portions 35 (FIG. 8A).

Next, the sintering material 31′ is sintered (FIG. 8B). As a result, the underlying member 31 is formed from the sintering material 31′.

Next, the underlying member 31 is removed from the sintering mold 35 (FIG. 8C). In the present embodiment, the plate-shaped portion 31a is formed from the sintering material 31′ supplied to the upper surface of the sintering mold 35, and the plurality of protrusions 31b are formed from the sintering material 31′ supplied into the plurality of recess portions 35a of the sintering mold 35. The shape of each of the protrusions 31b is, for example, a conical or pyramid shape according to the shape of each of the recess portions 35a.

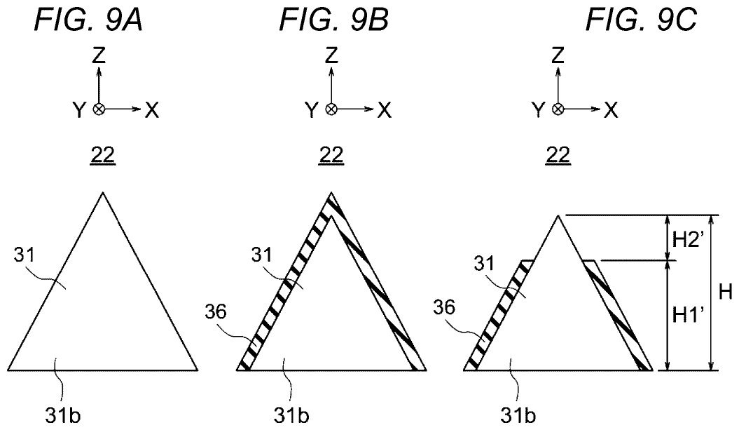

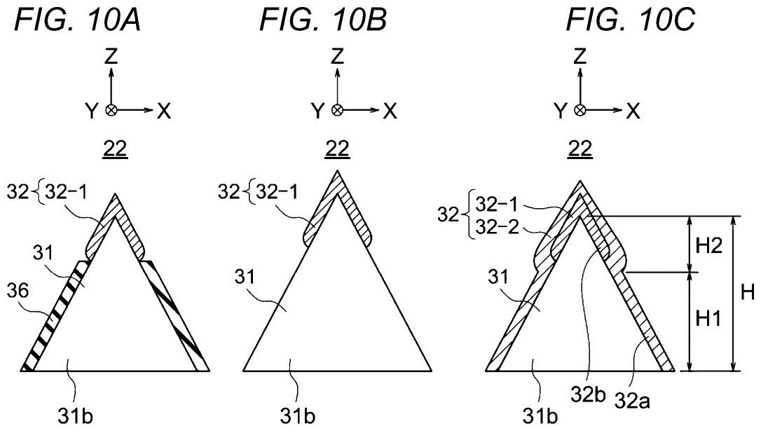

FIGS. 9A to 10C are cross-sectional views illustrating the method of manufacturing the dressing member 22 according to the first embodiment.

First, the underlying member 31 including the plate-shaped portion 31a and the plurality of protrusions 31b is prepared (FIG. 9A). FIG. 9A illustrates one of the protrusions 31b. For example, the underlying member 31 formed using the method of FIGS. 7A to 7C may be prepared, or the underlying member 31 formed using the method of FIGS. 8A to 8C may be prepared.

Next, a sacrifice layer 36 is formed on the underlying member 31 (FIG. 9B). As a result, the sacrifice layer 36 is formed on the upper surface Sa of the plate-shaped portion 31a or the surface of each of the protrusions 31b. The sacrifice layer 36 is, for example, a Si layer or a SiO₂ layer. The sacrifice layer 36 can protect the underlying member 31 from etching. The sacrifice layer 36 is an example of a first film.

Next, a part of the sacrifice layer 36 on each of the protrusions 31b is removed by etching (FIG. 9C). As a result, the upper end E of each of the protrusions 31b, a part of the surface S1, and a part of the surface S2 (refer to FIG. 3) are exposed from the sacrifice layer 36. Etching of FIG. 9C is, for example, dry etching or wet etching. Etching of FIG. 9C is an example of a first process.

FIG. 9C also illustrates the height H from the upper surface Sa of the plate-shaped portion 31a to the upper end E of each of the protrusions 31b as in FIG. 3. FIG. 9C also illustrates a height H1′ from the upper surface Sa of the plate-shaped portion 31a to the upper end of the sacrifice layer 36 and a height H2′ from the upper end of the sacrifice layer 36 to the upper end E of each of the protrusions 31b. The heights H1′ and H2′ are values close to the values of the above-described heights H1 and H2, respectively. The heights H, H1′, and H2′ satisfy a relationship of H=H1′+H2′. The height H2′ is, for example, 10 to 50 μm. The upper end of the sacrifice layer 36 in FIG. 9C has an annular shape in a plan view.

Next, a lower layer 32-1 that is a part of the film 32 is formed on the surface of each of the protrusions 31b by chemical vapor deposition (CVD) (FIG. 10A). As a result, the lower layer 32-1 is selectively formed on exposed portions of each of the protrusions 31b exposed from the sacrifice layer 36 by etching of FIG. 9C. A film thickness of the lower layer 32-1 according to the present embodiment changes near the upper end of the sacrifice layer 36, and is substantially fixed at positions away from the upper end. The film thickness of the lower layer 32-1 at the positions away from the upper end is, for example, 1 μm or more and 5 μm or less. The lower layer 32-1 is, for example, a diamond layer.

Next, the sacrifice layer 36 on the underlying member 31 is removed by etching (FIG. 10B). As a result, the remaining part of the sacrifice layer 36 on each of the protrusions 31b or the sacrifice layer 36 on the plate-shaped portion 31a is removed. Etching of FIG. 10B is wet etching or etch-back. Etching of FIG. 10B is an example of a second process.

Next, an upper layer 32-2 that is the remaining part of the film 32 is formed on the upper surface Sa of the plate-shaped portion 31a and the surface of each of the protrusions 31b (FIG. 10C). As a result, the upper layer 32-2 is formed on the exposed portion of each of the protrusions 31b and the plate-shaped portion 31a exposed from the sacrifice layer 36 by etching of FIG. 10B. The upper layer 32-2 is also formed on the exposed portion of each of the protrusions 31b exposed from the sacrifice layer 36 by etching of FIG. 9C with the lower layer 32-1 interposed therebetween. That is, the upper layer 32-2 is formed on the underlying member 31 and the lower layer 32-1. A film thickness of the upper layer 32-2 is, for example, 1 μm or more. The upper layer 32-2 is, for example, a diamond layer. In the present embodiment, the lower layer 32-1 and the upper layer 32-2 are formed of the same material (for example, diamond). The lower layer 32-1 and the upper layer 32-2 may be indistinguishable between each other or may be distinguishable between each other by film property of the lower layer 32-1 and film property of the upper layer 32-2 being different from each other.

In the present embodiment, the film 32 is formed of the lower layer 32-1 and the upper layer 32-2. As a result, the film 32 is formed to include the lower region 32a having the film thickness T1 and the plurality of upper regions 32b having the film thickness T2 (refer to FIG. 3). In FIG. 10C, the lower region 32a is formed of only the lower layer 32-1, and the upper region 32b is formed of the lower layer 32-1 and the upper layer 32-2. As in FIG. 3, FIG. 10C also illustrates the height H1 from the upper surface Sa of the plate-shaped portion 31a to the boundary between the lower region 32a and the upper region 32b and the height H2 from the same boundary to the upper end E of each of the protrusions 31b.

In FIG. 9C, as described above, the upper end E of the protrusion 31b, a part of the surface S1, and a part of the surface S2 are exposed from the sacrifice layer 36. As a result, in FIG. 10C, the upper region 32b is formed on the upper end E, the surface S1, and the surface S2 of the protrusion 31b, and is formed such that the upper end E is interposed between the surface S1 and the surface S2 in the XZ cross-section of the protrusion 31b.

As such, the dressing member 22 illustrated in FIG. 3 is manufactured. Next, one or a plurality of dressing members 22 are mounted on the support member 21. As a result, the dresser 2 according to the present embodiment is manufactured. When the dressing member 22 manufactured using the methods illustrated in FIGS. 9A to 10C is formed in a wafer, the wafer is diced into a plurality of chips before mounting.

As described above, the film 32 according to the present embodiment is formed such that the film thickness T2 of the upper region 32b is thicker than the film thickness T1 of the lower region 32a. That is, the film 32 is formed to be thick near the upper end E. Accordingly, in the present embodiment, a suitable film 32 can be formed on the surface of the protrusion 31b for dressing such that, for example, deterioration of polishing performance of the dresser 2 can be prevented.

### Second Embodiment

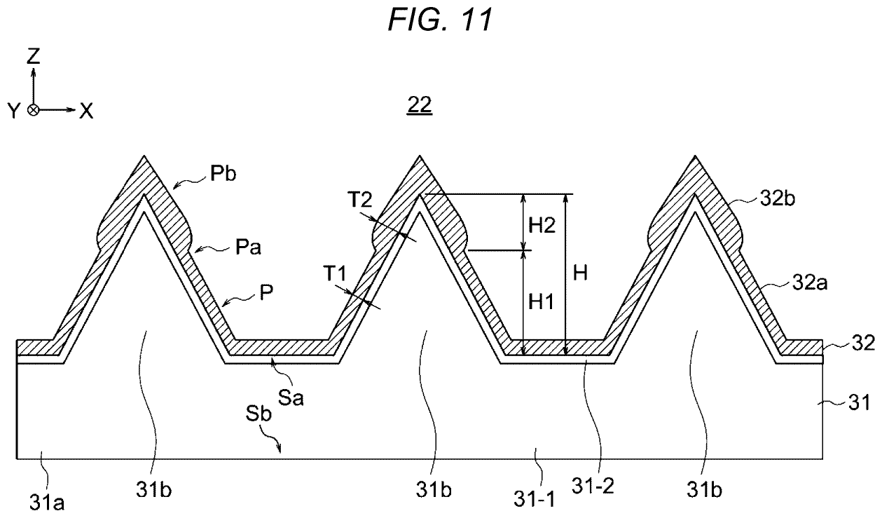

FIG. 11 is a cross-sectional view illustrating a structure of a dressing member 22 according to a second embodiment.

The dressing member 22 (FIG. 11) according to the present embodiment has the same structure as the dressing member 22 (FIG. 3) according to the first embodiment. The underlying member 31 according to the present embodiment includes a substrate 31-1 that is an example of a third layer and a coating layer 31-2 that is an example of a fourth layer.

The substrate 31-1 is, for example, a Si substrate. The substrate 31-1 according to the present embodiment forms most of the plate-shaped portion 31a and most of each of the protrusions 31b, and has a shape similar to the shape of the underlying member 31 according to the first embodiment.

The coating layer 31-2 is, for example, a carbon (C) layer other than a diamond layer. Examples of the carbon layer include a diamond-like carbon (DLC) layer and a hard C layer other than the DLC layer. The hard C layer has a Vickers hardness (HV) of, for example, 5000 or more. The coating layer 31-2 is formed on the substrate 31-1. A film thickness of the coating layer 31-2 according to the present embodiment is substantially fixed. The coating layer 31-2 according to the present embodiment is formed on the upper surface Sa of the plate-shaped portion 31a and the surface of each of the protrusions 31b.

The film 32 (diamond layer) according to the present embodiment is formed on the coating layer 31-2 of the plate-shaped portion 31a and each of the protrusions 31b. In general, the diamond layer is easily formed on a SiC layer such as a SiC substrate but is hard to be formed on a Si layer such as a Si substrate. Accordingly, the film 32 according to the present embodiment is hard to be formed on the substrate 31-1. Meanwhile, in general, the diamond layer is likely to be formed on the C layer. In the present embodiment, the substrate 31-1 is covered by the coating layer 31-2. As a result, the film 32 can be easily formed on the underlying member 31.

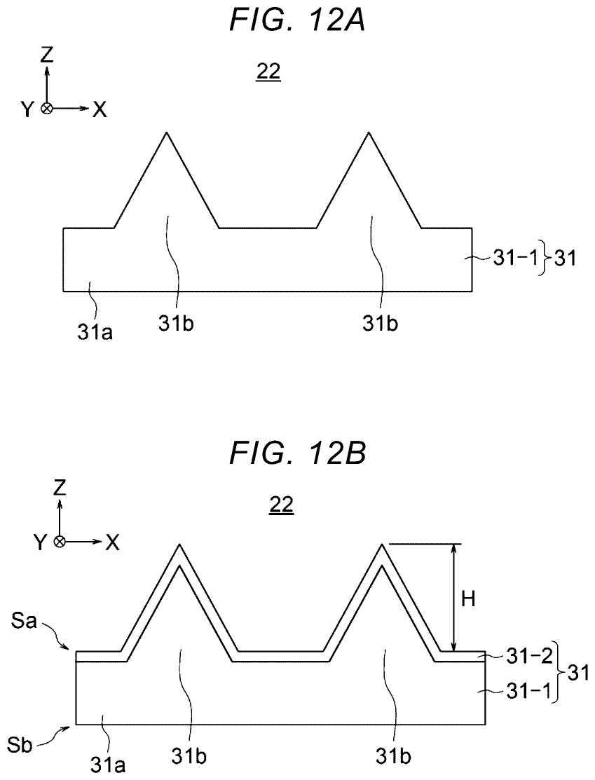

FIGS. 12A and 12B are cross-sectional views illustrating a method of manufacturing the dressing member 22 according to the second embodiment. FIGS. 12A and 12B illustrate a method of forming the underlying member 31 illustrated in FIG. 11.

First, the substrate 31-1 illustrated in FIG. 12A is prepared. For example, the substrate 31-1 may be formed using the method of forming the underlying member 31 of FIGS. 7A to 7C. A member as a substitute for the substrate 31-1 may be formed using the method of forming the underlying member 31 of FIGS. 8A to 8C.

Next, the coating layer 31-2 is formed on the substrate 31-1 (FIG. 12B). As such, the underlying member 31 illustrated in FIG. 11 is formed. When the method of FIGS. 8A to 8C is adopted, the coating layer 31-2 is formed on the member as a substitute for the substrate 31-1.

In the present embodiment, the underlying member 31 is formed of the substrate 31-1 and the coating layer 31-2. As a result, for example, even when the film 32 is hard to be formed on the substrate 31-1, the dressing member 22 can be easily manufactured.

### Third Embodiment

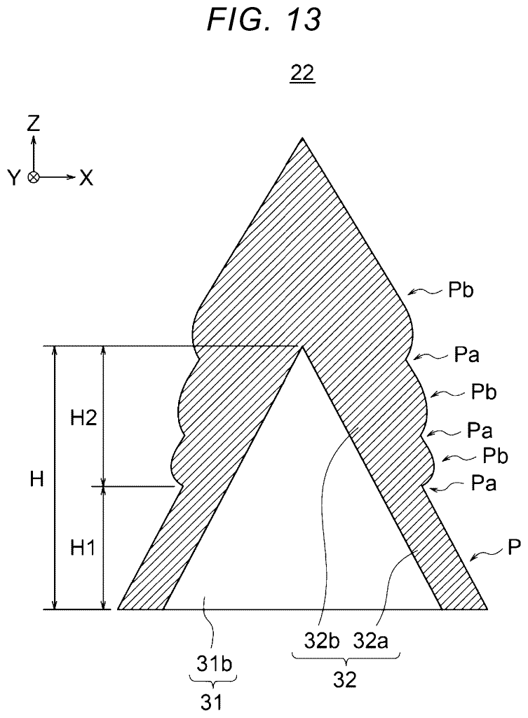

FIG. 13 is a cross-sectional view illustrating a structure of the dressing member 22 according to a third embodiment.

The dressing member 22 (FIG. 13) according to the present embodiment includes the underlying member 31 and the film 32 as in the dressing member 22 (FIG. 3) according to the first embodiment. A shape of the film 32 according to the present embodiment is different from the shape of the film 32 according to the first embodiment. FIG. 13 illustrates one of the plurality of protrusions 31b in the underlying member 31.

In the present embodiment, a plurality of portions Pa and a plurality of portions Pb are alternately provided in the Z direction on the surface of the film 32 on each of the protrusions 31b. Each of the portions Pb is on the surface of the upper region 32b, and protrudes from the portion P in a direction away from the surface of the protrusion 31b. Meanwhile, each of the portions Pa is a surface between the portions Pb adjacent to each other or a surface between the portion P and the lowermost portion Pb, and is recessed between the portions Pb adjacent to each other or between the portion P and the lowermost portion Pb. That is, the surface of the film 32 according to the present embodiment is recessed in each of the portions Pa. In the present embodiment, a shape of each of the portions Pa in a plan view is annular. The surface of the film 32 according to the present embodiment is recessed in each of the portions Pa, and protrudes in each of the portions Pb.

Hereinafter, in FIG. 13, the film 32 of the lowermost portion Pb is referred to as a first portion, the film 32 in the intermediate portion Pb is referred to as a second portion, and the film 32 in the uppermost portion Pb is referred to as a third portion. In FIG. 13, a film thickness of the first portion is thicker than a film thickness of an upper region 32a, a film thickness of the second portion is thicker than the film thickness of the first portion, and a film thickness of the third portion is thicker than the film thickness of the second portion. The film 32 can be formed by repeating the above-described process of forming the lower layer 32-1 three times. In FIG. 13, the surface of the film 32 is recessed near a boundary between the upper region 32a and the first portion, near a boundary between the first portion and the second portion, and near a boundary between the second portion and the third portion.

The film 32 according to the present embodiment may include N portions (N is an integer of 2 or more) including the first portion to an N-th portion. The film 32 can be formed by repeating the above-described process of forming the lower layer 32-1 N times. Here, the film thickness of the first portion is thicker than the film thickness of the upper region 32a, and the film thickness of a K-th portion (K is an integer satisfying 2≤K≤N) is thicker than the film thickness of a K−1-th portion. The K-th portion is positioned on a side of the upper end E of the protrusion 31b relative to the K−1-th portion. Here, the surface of the film 32 (e.g., recessed surface) is recessed near a boundary between the K−1-th portion and the K-th portion. For example, the recessed surface of the film 32 may include the boundary between the K−1-th portion and the K-th portion.

In the present embodiment, the film 32 near the upper end E of each of the protrusions 31b can be made thicker, and deterioration of polishing performance of the dresser 2 can be more effectively prevented. In the present embodiment, the plurality of protrusions or the plurality of recess portions can be formed on the surface of the film 32, and polishing performance of the dresser 2 can be further improved by the protrusions and the recess portions.

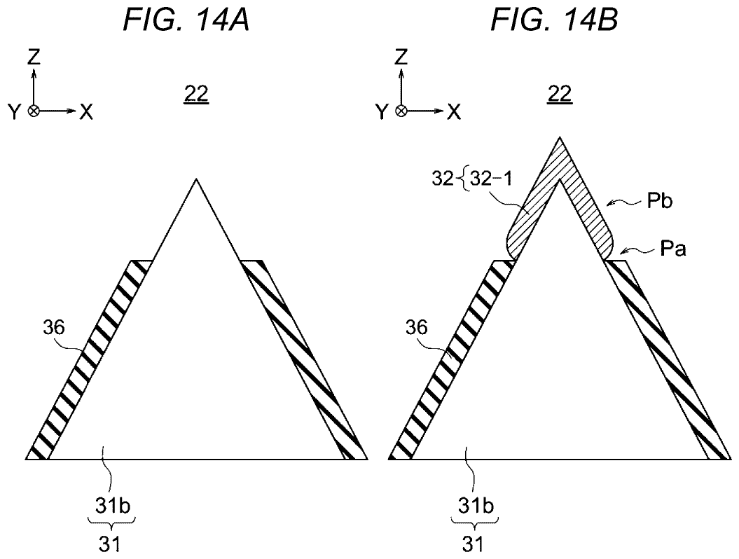

FIGS. 14A to 17B are cross-sectional views illustrating a method of manufacturing the dressing member 22 according to the third embodiment.

First, as in the step illustrated in FIG. 9A, the underlying member 31 including the plate-shaped portion 31a and the plurality of protrusions 31b is prepared (FIG. 14A). FIG. 14A illustrates one of the protrusions 31b. Next, as in the step illustrated in FIG. 9B, the sacrifice layer 36 is formed on the underlying member 31 (FIG. 9B). The sacrifice layer 36 is an example of a first film. Next, as in the step illustrated in FIG. 9C, a part of the sacrifice layer 36 on each of the protrusions 31b is removed by etching (FIG. 14A). Etching of FIG. 14A is an example of a first process.

Next, as in the step illustrated in FIG. 10A, the lower layer 32-1 that is a part of the film 32 is formed on the surface of each of the protrusions 31b (FIG. 14B). As a result, the lower layer 32-1 is selectively formed on the exposed portion of each of the protrusions 31b exposed from the sacrifice layer 36 by etching of FIG. 14A. FIG. 14B illustrates one portion Pa and one portion Pb formed on the surface of each of the protrusions 31b. The lower layer 32-1 formed in FIG. 14B is, for example, a diamond layer.

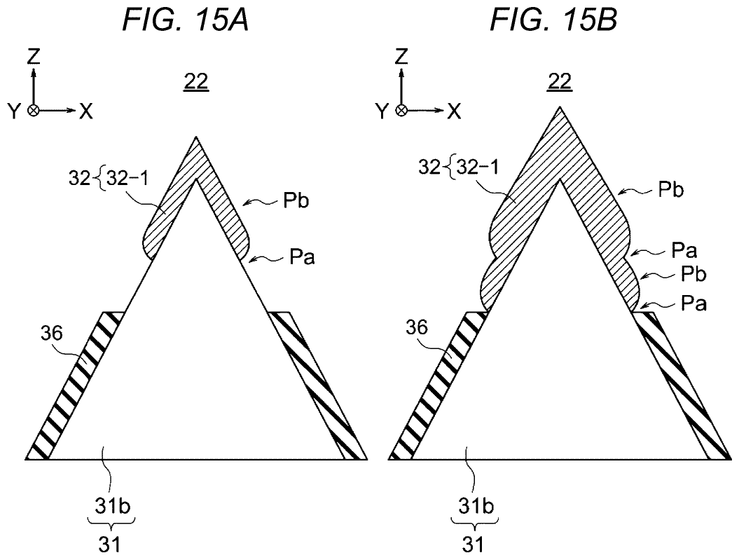

Next, a part of the sacrifice layer 36 on each of the protrusions 31b is removed by etching (FIG. 15A). As a result, a part of the surface of each of the protrusions 31b is exposed from the sacrifice layer 36 between the lower layer 32-1 and the sacrifice layer 36. Etching of FIG. 15A is, for example, dry etching or wet etching. Etching of FIG. 15A is also an example of the first process.

Next, the lower layer 32-1 that is a part of the film 32 is formed again on the surface of each of the protrusions 31b (FIG. 15B). As a result, the lower layer 32-1 is selectively formed on the exposed portion of each of the protrusions 31b exposed from the sacrifice layer 36 by etching of FIG. 15A. The lower layer 32-1 is further formed on the exposed portion of each of the protrusions 31b exposed from the sacrifice layer 36 by etching of FIG. 14A with the existing lower layer 32-1 formed in FIG. 14B interposed therebetween. That is, the lower layer 32-1 of FIG. 15B is formed on the underlying member 31 and the lower layer 32-1 of FIG. 14B. FIG. 15B illustrates two portions Pa and two portions Pb formed on the surface of each of the protrusions 31b. The lower layer 32-1 formed in FIG. 15B is, for example, a diamond layer. In FIG. 15B, the lower layer 32-1 formed in FIG. 14B and the lower layer 32-1 formed in FIG. 15B are illustrated as one lower layer 32-1.

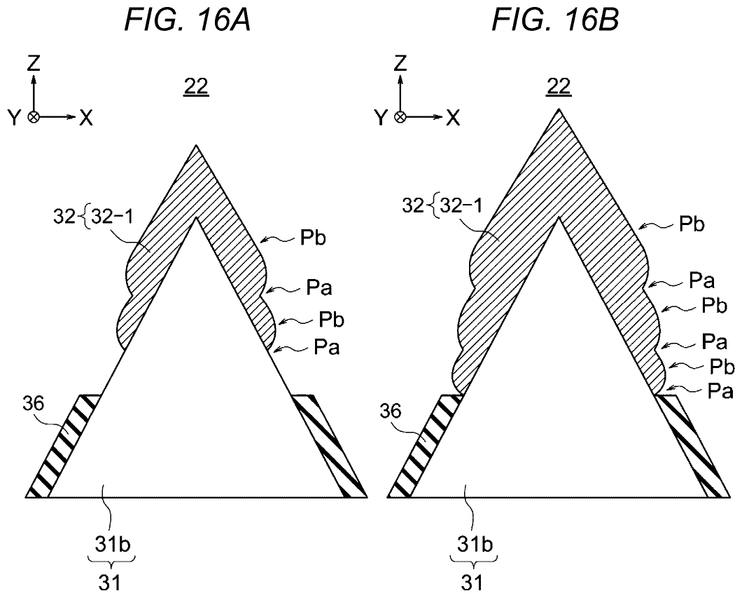

Next, a part of the sacrifice layer 36 on each of the protrusions 31b is removed by etching (FIG. 16A). As a result, a part of the surface of each of the protrusions 31b is exposed from the sacrifice layer 36 between the lower layer 32-1 and the sacrifice layer 36. Etching of FIG. 16A is, for example, dry etching or wet etching. Etching of FIG. 16A is also an example of the first process.

Next, the lower layer 32-1 that is a part of the film 32 is formed again on the surface of each of the protrusions 31b (FIG. 16B). As a result, the lower layer 32-1 is selectively formed on the exposed portion of each of the protrusions 31b exposed from the sacrifice layer 36 by etching of FIG. 16A. The lower layer 32-1 is further formed on the exposed portion of each of the protrusions 31b exposed from the sacrifice layer 36 by etching of FIGS. 14A and 15A with the existing lower layer 32-1 formed in FIGS. 14B and 15B interposed therebetween. That is, the lower layer 32-1 of FIG. 16B is formed on the underlying member 31 and the lower layer 32-1 of FIGS. 14B and 15B. FIG. 16B illustrates three portions Pa and three portions Pb formed on the surface of each of the protrusions 31b. The lower layer 32-1 formed in FIG. 16B is, for example, a diamond layer. In FIG. 16B, the lower layer 32-1 formed in FIG. 14B, the lower layer 32-1 formed in FIG. 15B, and the lower layer 32-1 formed in FIG. 16B are illustrated as one lower layer 32-1.

As such, in the steps illustrated in FIGS. 14A to 16B, multiple times of the etching step and multiple times of the CVD step are alternately repeated.

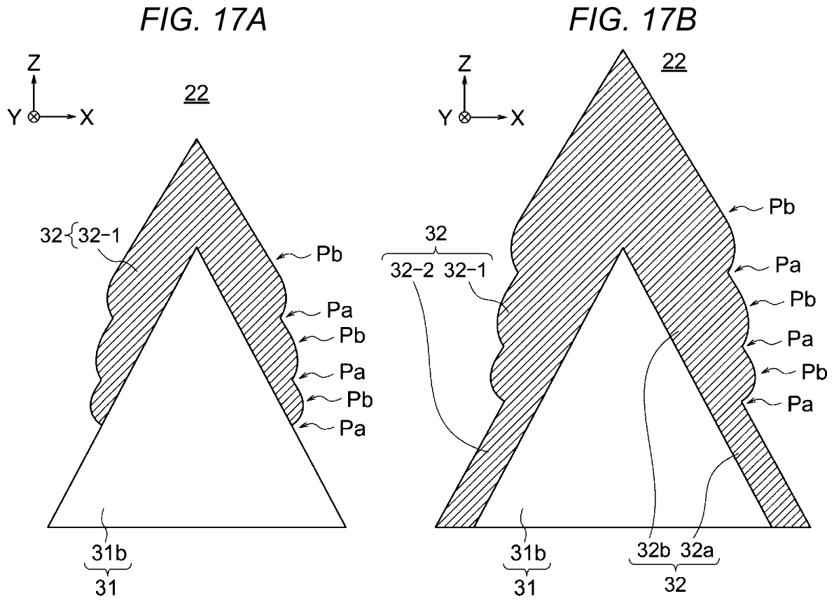

Next, as in the step illustrated in FIG. 10B, the sacrifice layer 36 on the underlying member 31 is removed by etching (FIG. 17A). As a result, the remaining part of the sacrifice layer 36 on each of the protrusions 31b and the sacrifice layer 36 on the plate-shaped portion 31a are removed. Etching of FIG. 17A is wet etching or etch back. Etching of FIG. 17A is an example of a second process.

Next, as in the step illustrated in FIG. 10C, the upper layer 32-2 that is the remaining part of the film 32 is formed on the upper surface Sa of the plate-shaped portion 31a or the surface of each of the protrusions 31b (FIG. 17B). As a result, the upper layer 32-2 is formed on the exposed portion of each of the protrusions 31b and the plate-shaped portion 31a exposed from the sacrifice layer 36 by etching of FIG. 17A. The upper layer 32-2 is further formed on the exposed portion of each of the protrusions 31b exposed from the sacrifice layer 36 by etching of FIGS. 14A, 15A, and 16B with the lower layer 32-1 interposed therebetween. That is, the upper layer 32-2 is formed on the underlying member 31 and the lower layer 32-1. FIG. 17B illustrates three portions Pa and three portions Pb formed on the surface of each of the protrusions 31b. The upper layer 32-2 is, for example, a diamond layer. In FIG. 17B, the lower layer 32-1 and the upper layer 32-2 are illustrated as one film 32.

As such, the dressing member 22 illustrated in FIG. 13 is manufactured. Next, one or a plurality of dressing members 22 are mounted on the support member 21. As a result, the dresser 2 according to the present embodiment is manufactured.

Accordingly, in the present embodiment, a suitable film 32 can be formed on the surface of the protrusion 31b for dressing such that, for example, the film 32 near the upper end E of each of the protrusions 31b can be made thicker.

### Fourth Embodiment

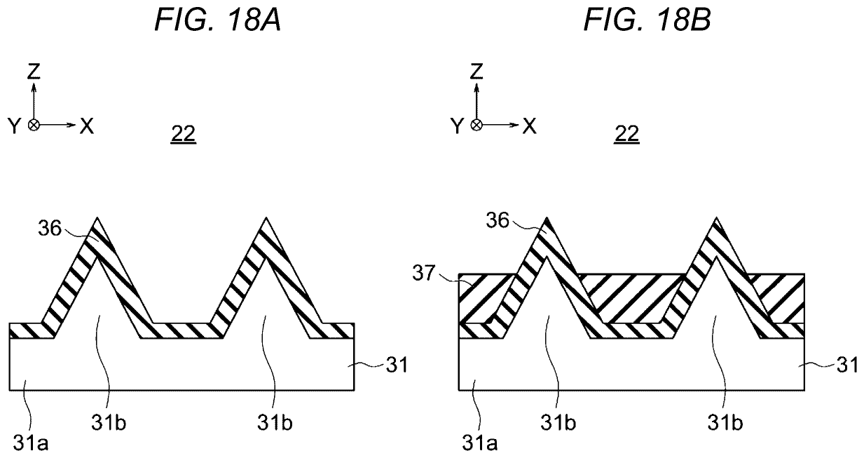

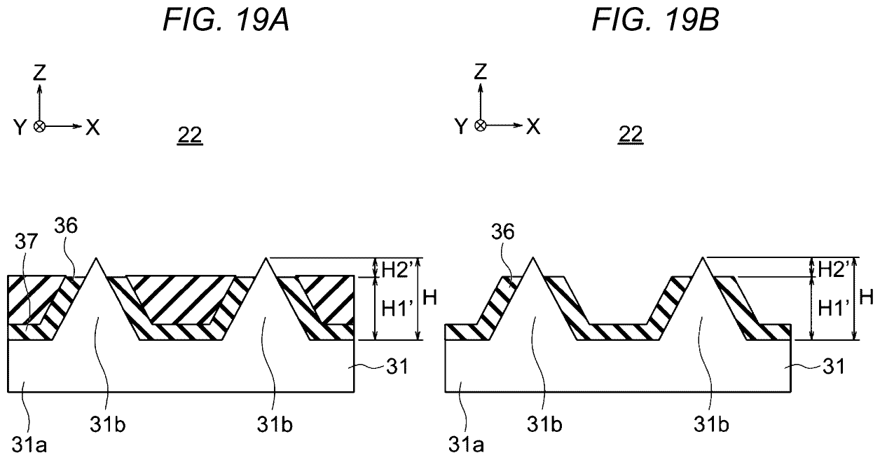

FIGS. 18A to 19B are cross-sectional views illustrating a method of manufacturing the dressing member 22 according to a fourth embodiment. FIGS. 18A to 19B illustrate examples of the steps of FIGS. 9B and 9C.

First, the sacrifice layer 36 is formed on the underlying member 31 (FIG. 18A). As a result, the sacrifice layer 36 is formed on the upper surface Sa of the plate-shaped portion 31a and the surface of each of the protrusions 31b. The sacrifice layer 36 is, for example, a Si layer or a SiO₂ layer. The Si layer may be an amorphous silicon layer or a polysilicon layer. The sacrifice layer 36 can protect the underlying member 31 from etching. The sacrifice layer 36 is an example of a first film.

Next, an embedding layer (filling layer) 37 is formed on the sacrifice layer 36 (FIG. 18B). As a result, gaps between the protrusions 31b are embedded with the embedding layer 37. The embedding layer 37 is, for example, a coating film formed by applying a coating solution on the surface of the sacrifice layer 36. The embedding layer 37 is formed such that the sacrifice layer 36 is partially covered by the embedding layer 37. In FIG. 18B, a lower portion of the sacrifice layer 36 is covered by the embedding layer 37, and an upper portion of the sacrifice layer 36 is exposed from the embedding layer 37. The embedding layer 37 can protect the sacrifice layer 36 from etching. The embedding layer 37 is an example of a second film.

Next, while the sacrifice layer 36 is partially covered by the embedding layer 37, the sacrifice layer 36 is processed by etching (FIG. 19A). As a result, a part of the sacrifice layer 36 on each of the protrusions 31b is removed by etching. Specifically, the exposed portion of the sacrifice layer 36 exposed from the embedding layer 37 is removed by etching. Etching of FIG. 19A is, for example, dry etching or wet etching. Etching of FIG. 19A is an example of a first process.

Next, the embedding layer 37 is removed by etching (FIG. 19B). As a result, a structure illustrated in FIG. 9C is implemented. Etching of FIG. 19B is, for example, dry etching or wet etching. Embedding layer 37 may be removed by ashing.

When the sacrifice layer 36 is a SiO₂ layer, the embedding layer 37 is, for example, a photoresist layer or a spin-on carbon (SOC) layer. Here, etching of FIG. 19A is performed, for example, by dry etching using CF-based gas or CHF-based gas (for example, C₄F₈ gas, C₄F₆ gas, or CH₂F₂ gas), Ar gas, and O₂ gas or by wet etching using hydrofluoric acid or buffered hydrofluoric acid (C represents carbon, F represents fluorine, H represents hydrogen, Ar represents argon, and O represents oxygen). The process of FIG. 19B is performed, for example, by ashing or using a sulfuric peroxide mixture (SPM) or a resist stripping solution.

Meanwhile, when the sacrifice layer 36 is a Si layer, the embedding layer 37 is, for example, a photoresist layer, an SOC layer, a SiOCH layer, a SiO₂ layer, a polysilazane layer, or a spin-on glass (SOG) layer. Here, etching of FIG. 19A is performed, for example, by dry etching using HBrCl₂ gas, SF₆ gas, or NF₃ gas or by wet etching using phosphoric acid (Br represents bromine, Cl represents chlorine, S represents sulfur, and N represents nitrogen). When the embedding layer 37 is a photoresist layer, an SOC layer, or a SiOCH layer, the process of FIG. 19B is performed, for example, by dry etching using CF-based gas such as C₅F₈ gas and Ar gas or by dry etching using CF-based gas such as C₅F₈ gas, Ar gas, and O₂ gas. Further, when the embedding layer 37 is a SiO₂ layer, a polysilazane layer, or an SOG layer, the process of FIG. 19B is performed, for example, by dry etching using CF-based gas or CHF-based gas (for example, C₄F₈ gas, C₄F₆ gas, or CH₂F₂ gas), Ar gas, and O₂ gas or by wet etching using hydrofluoric acid or buffered hydrofluoric acid.

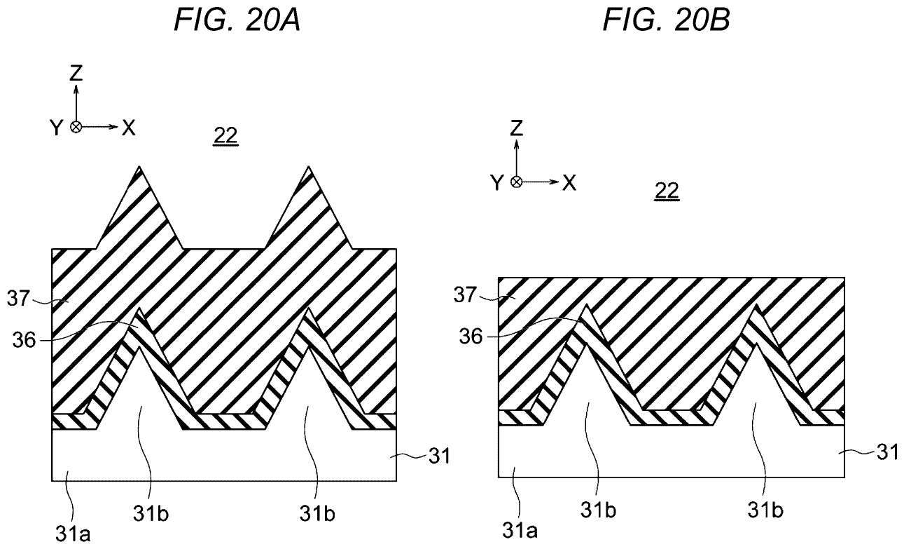

FIGS. 20A and 20B are cross-sectional views illustrating a method of manufacturing the dressing member 22 according to a modification example of the fourth embodiment. The structure illustrated in FIG. 18B may be implemented using the method according to the present modification example.

First, the embedding layer 37 is formed on the sacrifice layer 36 (FIG. 20A). The embedding layer 37 according to the present modification example is formed to completely cover the sacrifice layer 36. The embedding layer 37 according to the present modification example may be a coating film or a non-coating film.

Next, the surface of the embedding layer 37 is planarized by CMP (FIG. 20B). As a result, the surface of the embedding layer 37 changes from an uneven surface to a flat surface.

Next, the embedding layer 37 is processed by dry etching or wet etching. As a result, the embedding layer 37 changes to the shape illustrated in FIG. 18B.

When the sacrifice layer 36 is a SiO₂ layer and the embedding layer 37 is a photoresist layer or an SOC layer, etching is performed, for example, by RIE using O₂ gas. When the sacrifice layer 36 is a Si layer and the embedding layer 37 is a photoresist layer, an SOC layer, or a SiOCH layer, etching is performed, for example, by dry etching using CF-based gas such as C₅F₈ gas and Ar gas or by dry etching using CF-based gas such as C₅F₈ gas, Ar gas, and O₂ gas. When the sacrifice layer 36 is a Si layer and the embedding layer 37 is a SiO₂ layer, a polysilazane layer, or an SOG layer, etching is performed, for example, by dry etching using CF-based gas or CHF-based gas (for example, C₄F₈ gas, C₄F₆ gas, or CH₂F₂ gas), Ar gas, and O₂ gas.

In the present embodiment, steps of FIGS. 9B and 9C can be implemented using the embedding layer 37.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A dresser comprising:
a first layer including a portion and a protrusion provided on the portion; and
a second layer including a first region provided on the protrusion and having a first thickness and a second region provided on the protrusion and having a second thickness thicker than the first thickness, the second region being positioned on a side of an upper end of the protrusion relative to the first region, wherein
in a cross-section including the upper end of the protrusion, the protrusion includes a first surface positioned on one side of the upper end of the protrusion and a second surface positioned on another side of the upper end of the protrusion, and
the second region is provided on the upper end, the first surface, and the second surface of the protrusion.

2. The dresser according to claim 1, wherein the first layer includes at least one of a silicon layer or a silicon carbide layer.

3. The dresser according to claim 1, wherein the second layer includes at least one of a diamond layer or a diamond-like carbon (DLC) layer.

4. The dresser according to claim 1, wherein
a shape of the protrusion is a conical or pyramid shape, and
the upper end of the protrusion is an apex of the conical or pyramid shape.

5. The dresser according to claim 1, wherein the first region surrounds the second region in a plan view, and the second region overlaps the upper end of the protrusion in a plan view.

6. The dresser according to claim 1, wherein a surface of the second layer includes a recessed surface, and
the recessed surface includes a boundary between the first region and the second region.

7. The dresser according to claim 1, wherein
the first thickness is 1 μm or more, and
a difference obtained by subtracting the first thickness from the second thickness is 1 μm or more.

8. The dresser according to claim 1, wherein the first layer includes a third layer and a fourth layer provided on the third layer.

9. The dresser according to claim 8, wherein the third layer is a silicon layer, and the fourth layer is a carbon layer.

10. The dresser according to claim 1, wherein
the second region includes first to N-th portions (N is an integer of 2 or more) each having a respective one of first to N-th portion thicknesses,
the first portion of the second region is positioned on a side of the upper end of the protrusion relative to the first region and has the first portion thickness thicker than the first thickness, and
the K-th portion (K is an integer satisfying 2≤K≤N) of the second region is positioned on a side of the upper end of the protrusion relative to the K−1-th portion and has a K-th portion thickness thicker than a K−1-th portion thickness.

11. The dresser according to claim 10, wherein the second layer includes a recessed surface, and
The recessed surface of the second layer includes a boundary between the K−1-th portion and the K-th portion.

12. The dresser according to claim 1, further comprising:
a support plate; and
a dressing chip provided on the support member, wherein
the dressing chip includes the first layer and the second layer.

13. A method of manufacturing a dresser, the method comprising:
forming a first layer including a portion and a protrusion provided on the portion; and
forming a second layer including a first region provided on the protrusion and having a first thickness and a second region provided on the protrusion and having a second thickness thicker than the first thickness, the second region being positioned on a side of an upper end of the protrusion relative to the first region, wherein
the protrusion is formed such that a cross-section including the upper end of the protrusion includes a first surface positioned on one side of the upper end of the protrusion and a second surface positioned on another side of the upper end of the protrusion, and
the second region is formed on the upper end, the first surface, and the second surface of the protrusion.

14. The method of manufacturing a dresser according to claim 13, wherein the portion and the protrusion are formed by etching the first layer.

15. The method of manufacturing a dresser according to claim 13, wherein the portion and the protrusion are formed by forming the first layer using a sintering material.

16. The method of manufacturing a dresser according to claim 13, wherein the second layer is formed by
forming a first film on the protrusion,
removing a part of the first film by a first process and forming a lower layer of the second layer on an exposed portion of the protrusion exposed from the first film by the first process, and
removing a remaining part of the first film by a second process and forming an upper layer of the second layer on the lower layer and an exposed portion of the protrusion exposed from the first film by the second process.

17. The method of manufacturing a dresser according to claim 16, wherein the first process is performed while the first film is partially covered by a second film.

18. The method of manufacturing a dresser according to claim 13, wherein
the second region is formed to include first to N-th portions (N is an integer of 2 or more) each having a respective one of first to N-th portion thicknesses,
the first portion of the second region is formed to be positioned on a side of the upper end of the protrusion relative to the first region and have the first portion thickness thicker than the first thickness, and
the K-th portion (K is an integer satisfying 2≤K≤N) of the second region is formed to be positioned on a side of the upper end of the protrusion relative to a K−1-th portion and have the K-th portion thickness thicker than a K−1-th portion thickness.

19. The method of manufacturing a dresser according to claim 18, wherein the second layer is formed by
forming a first film on the protrusion,
alternately repeating removal of a part of the first film by a first process and formation of a lower layer of the second layer on an exposed portion of the protrusion exposed from the first film by the first process, and
removing a remaining part of the first film by a second process and forming an upper layer of the second layer on the lower layer and an exposed portion of the protrusion exposed from the first film by the second process.

20. A method of manufacturing a semiconductor device, the method comprising:
dressing a polishing pad using a dresser;
after dressing the polished pad, polishing a wafer using the polishing pad; and
after polishing the wafer, manufacturing a semiconductor device using the wafer, wherein
the dresser includes
a first layer including a portion and a protrusion provided on the portion, and
a second layer including a first region provided on the protrusion and having a first thickness and a second region provided on the protrusion, and having a second thickness thicker than the first thickness, the second region being positioned on a side of an upper end of the protrusion relative to the first region
in a cross-section including the upper end of the protrusion, the protrusion includes a first surface positioned on one side of the upper end of the protrusion and a second surface positioned on another side of the upper end of the protrusion, and
the second region is provided on the upper end, the first surface, and the second surface of the protrusion.
